(19) United States
(12) Patent Application Publication
(10) Pub. No.: US 2026/0305018 A1
(43) Pub. Date: Oct. 1, 2026

(54) OPTICALLY POWERED SEMICONDUCTOR CIRCUIT ASSEMBLY FOR LIGHT-ILLUMINATED FLUID CONTAINERS

(71) Applicant: OWiC Technologies Inc., Ithaca, NY (US)

(72) Inventors: Alejandro J. Cortese, Ithaca, NY (US); Michael F. Reynolds, Ithaca, NY (US); Kevin Sun, Ithaca, NY (US); Song Lin, Ithaca, NY (US); Paul L. McEuen, Ithaca, NY (US)

(73) Assignee: OWiC Tecnologies, Inc., Ithaca, NY (US)

(21) Appl. No.: 19/575,769

(22) Filed: Mar. 23, 2026

Related U.S. Application Data
(60) Provisional application No. 63/778,305, filed on Mar. 26, 2025.

(51) Int. Cl. H10F 77/00; H10F 77/50

(52) U.S. Cl. CPC H10F 77/955; H10F 77/50

(57) ABSTRACT

An optically powered semiconductor circuit assembly configured for use in a light-illuminated fluid container includes a semiconductor circuit comprising one or more photovoltaic elements configured to generate power when illuminated by light and a flexible component mechanically coupled to the semiconductor circuit. The flexible component is configured to deform upon insertion into the fluid container, such that the deformation secures the assembly in a fixed position and orientation within the fluid container. The flexible component is also configured to hold the semiconductor circuit with the photovoltaic elements in a fixed orientation. The assembly allows fluid to access the semiconductor circuit during use.

### CROSS-REFERENCES TO RELATED APPLICATIONS

This application claims the benefit of priority to U.S. Provisional Patent Application No. 63/778,305, filed Mar. 26, 2025, entitled “OPTICALLY POWERED SEMICONDUCTOR CIRCUIT ASSEMBLY FOR LIGH-ILLUMINATED FLUID CONTAINERS,” the entire contents of which is hereby incorporated by reference for all purposes.

### SUMMARY OF THE INVENTION

There is a growing interest and need for miniaturized instrumentation within small-volume fluid containers commonly used in chemistry and biology, such as vials, drams, and well plates. These containers are standard across a wide range of workflows, from high-throughput reaction screening and parallel synthesis to diagnostics and biological assays. As experimental methods become more automated and parallelized, researchers and industry alike are seeking compact, embedded tools, such as sensors, actuators, transducers, and identification tags, that can operate directly within these containers to monitor, control, or annotate reactions and samples.

Concurrently, optical techniques have become increasingly prevalent in these fields. Photochemistry, fluorescence-based detection, and light-mediated control of chemical and biological systems all rely on the ability to couple light into fluid containers with precision. Despite these developments, there has been little progress in embedding wireless semiconductor circuitry into these optical workflows. Most instrumentation still requires wired connections, custom vessels, or manual setup, creating barriers to scale, reproducibility, and ease of use. A generalizable approach for integrating optically powered electronics into standard fluid containers could dramatically expand the functionality of these systems, but this remains largely unaddressed by current technologies.

Integrating optically powered semiconductor circuits into fluid containers, such as vials, drams, and well plates, holds transformative potential for chemical and biological research. These optically powered circuits can serve as wireless tools for driving electrochemical reactions, sensing environmental conditions, or uniquely identifying samples. Such technology is particularly attractive in high-throughput workflows, where hundreds or thousands of experiments are conducted in parallel, and where wired instrumentation is impractical. However, integration of these typically mm-scale light-powered devices into standard laboratory containers introduces a unique set of challenges. To realize the full utility of these systems, especially in industrial or pharmaceutical contexts, the integration must be robust, scalable, reproducible, and seamlessly compatible with existing infrastructure. The optically powered semiconductor circuit assembly for light-illuminated fluid containers disclosed address many integration requirements described below.

Placement and preloading of these devices is essential to usability and reproducibility. Without a stable fixture or insert, users must manually handle and orient each device, creating opportunities for error, inconsistency, or damage. A system where the semiconductor device is pre-installed and pre-aligned inside the container reduces user burden and eliminates ambiguity in orientation. In workflows using multiwell plates or blocks of vials, preloading enables batch handling, parallel setup, and compatibility with automated systems. For broader adoption, devices must arrive at the user site already placed in their correct position, securely mounted, and ready for illumination and fluid addition.

Centering for optical coupling is also critical. Light-powered circuits rely on receiving sufficient or uniform irradiance to activate and operate correctly. Illumination systems commonly used in laboratories, such as light emitting diode (LED) arrays in plate readers or photochemistry setups, exhibit spatial non-uniformity, typically with peak intensity near the center of the light emitting element. Devices that are off-center with respect to that light source within a well or vial may receive only a fraction of the required light, leading to incomplete reactions or unpredictable behavior. Additionally, refraction and reflection at the container boundaries can distort or scatter incoming light if the device is not properly aligned. An assembly that ensures consistent centering and fixed angular orientation with respect to the incoming light beam is necessary for reliable, reproducible performance.

Precise positioning and orientation of the device within the fluid container ensures that the photodiodes are consistently exposed to light and that any active surfaces—such as electrodes or sensors—remain accessible to the fluid. These devices are inherently directional: if they rotate or flip due to buoyancy, surface tension, or agitation, they may cease to function. Typically optically wireless circuits have a side with photovoltaics and an opaque substrate underneath that prevents light from hitting the photovoltaics when illuminated from one side. In particular, small-scale mm-scale devices can easily float, stick to the container wall, or become lodged in a region where light and fluid access are reduced. An insert that secures the device into a fixed location—both centered and at a specific depth in the fluid container—and orientation while resisting these perturbative forces enables stable and predictable operation.

Shipping robustness is a prerequisite for any commercial deployment. Laboratory supplies routinely experience accelerations and impacts during transit. Even well-packed containers can be exposed to 1-5 g forces during standard handling, and up to 100 g if dropped. If the device dislodges or breaks loose during shipment, it may flip, crack, or become misaligned in a way that compromises experimental validity. A mechanically stable fixture or flexure that secures the device in place is necessary to ensure the system arrives intact and ready for use.

Compatibility with mixing techniques is essential for real-world laboratory protocols, which often include vortexing, shaking, or magnetic stirring to maintain homogeneous solutions or drive reaction kinetics. Bare chips floating freely in solution are susceptible to damage from stir bars or mechanical agitation. They can also migrate within the container, leading to variation in light exposure or loss of alignment. The present disclose isolates the semiconductor device from mechanical contact with mixing elements and holds it in position during all forms of agitation, protecting both the device and the integrity of the experiment.

Maximizing fluid flow and reagent access to the active surfaces of the device is crucial, especially in electrochemical applications. A device resting flat against the container bottom may occlude its own electrodes or create stagnant fluid zones. This can limit mass transport of chemicals or other fluid elements to the location of the semiconductor circuit or electrodes. The present disclosure lifts the wireless semiconductor circuit off the container surface and includes cutouts, channels, or angled fins that allow fluid to move freely around the device, even during active mixing. This ensures uniform reagent exposure, improved mass transport, and better electrochemical performance across a wide range of reaction types.

Chemical compatibility and long-term durability must also be considered. Laboratory containers may be filled with corrosive solvents, strong acids or bases, or sensitive biological fluids. Adhesives or composite materials may degrade, delaminate, or leach contaminants into the solution. In one embodiment, the present disclosure is composed of a single chemically resistant polymer—such as polypropylene or PTFE—which can withstand harsh environments while maintaining mechanical integrity.

Insertion through narrow openings, as found in screw-top vials or dram bottles, presents a geometric constraint that also must be overcome. In many containers, the mouth is narrower than the internal volume, making it impossible to insert a fully rigid assembly. A viable solution must accommodate this by allowing the insert to flex or rotate during insertion, then expand or reconfigure to fit securely within the container body. Designs that leverage compliant mechanisms to navigate this constraint enable compatibility with common labware.

Needing to have an assembly that holds an optically powered semiconductor chip but also can be secured to fluid containers also poses difficulties mechanical decoupling the mounting of the semiconductor from the mechanical attachment of the fixture to the fluid container. If the same mechanical deformation is used both to grip the container wall and hold the device, stresses and deformations can couple directly to the circuit, risking damage or dislodgment. The present disclosure isolates these two interfaces—in one embodiment, by supporting the circuit on a central frame connected to outer fixation arms with flexures. This prevents stress transfer and allows for greater mechanical robustness.

Finally, compatibility with parallel transfer into standard reactor formats is essential for high-throughput and automated workflows. Many laboratories rely on pitch-matched reactor blocks, automated fluid handlers, or photoreactors where arrays of containers must be aligned and moved simultaneously. Inserts must support these workflows, including operations like flipping a full set of vials into a reactor block or aligning a plate over an LED array. Designs that match standard pitches and support consistent vertical alignment are necessary for seamless integration into these systems.

Together, these ten requirements define the core challenge of deploying optically powered semiconductor devices in fluid containers. Existing approaches—such as manually dropping loose devices into wells or vials—fail to address most, if not all, of these criteria. Without a solution that meets them comprehensively, such devices remain fragile, error-prone, and impractical for widespread use.

The present disclosure addresses this unmet need by introducing a novel assembly that satisfies all of these requirements. This allows wireless semiconductor devices to be seamlessly embedded into standard fluid containers, enabling robust, scalable deployment of wireless photonic instrumentation for chemistry, biology, and beyond.

### BRIEF DESCRIPTION OF THE DRAWINGS

The accompanying drawings, which are incorporated in and constitute a part of this disclosure, illustrate various disclosed embodiments. In the drawings:

FIG. 1 shows bare optically powered semiconductor circuits without any fixtures and a standard 4 mm vial.

FIG. 2 illustrates configurations of bare optically powered semiconductor circuits in non-uniform light-illuminated fluid containers.

FIG. 3 shows an illumination source used in high-throughput biological and chemical experiments as well as data characterizing the spatial non-uniformity of the illuminator.

FIG. 4 shows one embodiment of the present disclosed optically powered semiconductor circuit assembly for light-illuminated fluid containers inside of an 8 mm diameter vial on a measurement reference surface.

FIG. 5 illustrates a cross section of one embodiment of the present disclosed optically powered semiconductor circuit assembly inside of a light-illuminated fluid container with fluid present.

FIG. 6 shows 3D renderings of one embodiment of fixtures used for the present disclosed optically powered semiconductor circuit assembly for light-illuminated fluid containers as well as manufactured embodiments of the fixtures.

FIG. 7 illustrates cross sectional views of one embodiment of the present disclosed optically powered semiconductor circuit assembly for light-illuminated fluid containers coupled to an optical illumination source and optical detector.

FIG. 8 illustrates a cross-sectional view of one embodiment of the present disclosed optically powered semiconductor circuit assembly for light-illuminated fluid containers coupled to an optical illumination source and optical detector with a magnetic stir bar system being simultaneously used.

FIG. 9 illustrates one embodiment of the present disclosed optically powered semiconductor circuit assembly for light-illuminated fluid containers with angled elements that promote the flow of fluid to the optically powered semiconductor circuit.

FIG. 10 illustrates cross-sectional views of a 96 well plate of vials under illumination with some embodiments of present disclosed optically powered semiconductor circuit assemblies for light-illuminated fluid containers.

FIG. 11 shows a pre-populated 96-well plate of vials with one embodiment of the present disclosed optically powered semiconductor circuit assembly for light-illuminated fluid containers in a container suitable for shipment.

FIG. 12 shows a zoomed in image of a prepopulated 96 well plate of vials with one embodiment of the present disclosed optically powered semiconductor circuit assembly for light-illuminated fluid containers.

FIG. 13 shows the process of insertion of optically powered semiconductor circuits through mechanical deformation into the flexible fixtures for an optically powered semiconductor circuit assembly for drams.

FIG. 14 shows various embodiments of the present disclosed optically powered semiconductor circuit assembly for light-illuminated dram vials.

FIG. 15 shows an embodiment of the present disclosed optically powered semiconductor circuit assembly for light-illuminated 384 well plates, another common platform for high-throughput experiments in chemistry and biology.

### DETAILED DESCRIPTION OF SPECIFIC EMBODIMENTS

The present disclosure relates to optically powered wireless semiconductor assemblies configured for integration into light-illuminated fluid containers used in chemical, biological, and other applications.

The following detailed description refers to the accompanying drawings. Wherever possible, the same reference numbers are used in the drawings and the following description to refer to the same or similar parts. While several illustrative embodiments are described herein, modifications, adaptations and other implementations are possible. For example, substitutions, additions or modifications may be made to the components illustrated in the drawings, and the illustrative methods described herein may be modified by substituting, reordering, removing, or adding steps to the disclosed methods. Accordingly, the following detailed description is not limited to the disclosed embodiments and examples. Instead, the proper scope is defined by the appended claims.

The disclosed embodiments enable the integration of optically powered semiconductor circuits into light-illuminated fluid containers in a way that meets the full set of practical, chemical, mechanical, and optical requirements necessary for real-world use in chemical, biological, and other applications. Unlike prior approaches that rely on manual placement of bare devices or integration of semiconductor circuits into custom fluid containers, the disclosed system provides a robust, chemically resistant mechanical assembly that holds the semiconductor circuit in a fixed position and orientation, allowing precise light delivery, effective fluid flow, and compatibility with stirring, shipping, and high-throughput handling. The design accommodates standard containers such as vials, drams, and well plates, and is compatible with aggressive solvents and acids, narrow container openings, and automated workflows. By addressing integration challenges—including centering, mixing resilience, mass transport optimization, orientation control, and optical communication alignment—this solution represents a novel enabling innovation for the deployment of wireless, optically powered electronics for microscale experimentation.

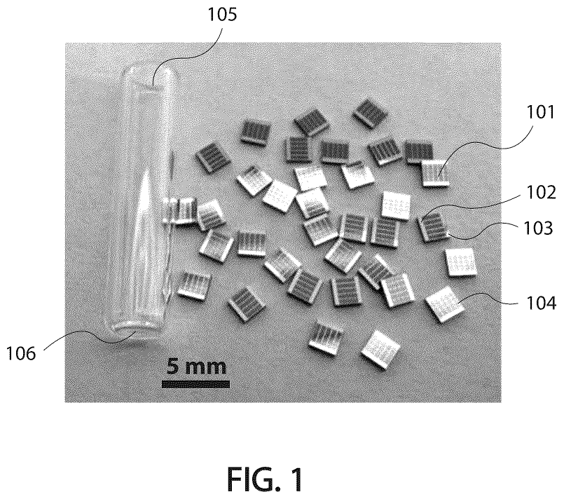

FIG. 1 shows bare optically powered semiconductor circuits without any fixtures and a standard 4 mm vial. The optically powered semiconductor circuits 101 are Small Photoelectronic ElectroChemical Synthesizers (SPECS) composed of an array of photovoltaics 104 and metal electrodes 102 and 103. These circuits are used for electrochemistry in drug discovery to run chemical processes when illuminate with light. As shown in FIG. 1 these circuits are bare, meaning they have been diced from a larger semiconductor wafer using a wafer dicing tool and no additional packaging has been carried out following dicing. Similar sized optical wireless integrated circuits have been developed previously that allow for transduction, sensing, and identification wireless using light for power and communication. The 4 mm diameter glass vial 106 is a standard fluid container size used in the drug discovery process and for electrochemistry more broadly. The opening of the vial 105 is not sealed and allows for fluid to be added. Typical fluid volumes in such vials would be less than 1 milliliter, with 50 microliters, 100 microliters, and 200 microliters being typical. A scale bar of 5 mm is also shown for scale.

In alternative embodiments, the semiconductor circuit may be affixed to the flexible component using an adhesive, such as a chemically resistant epoxy or UV-cured bonding agent. In some configurations, the flexible component itself may be secured within the fluid container using adhesive applied to its outer surface, rather than relying solely on mechanical deformation. These adhesive-based embodiments may be preferable in applications where mechanical deformation is limited or where fixture stability must be maintained with minimal insertion force.

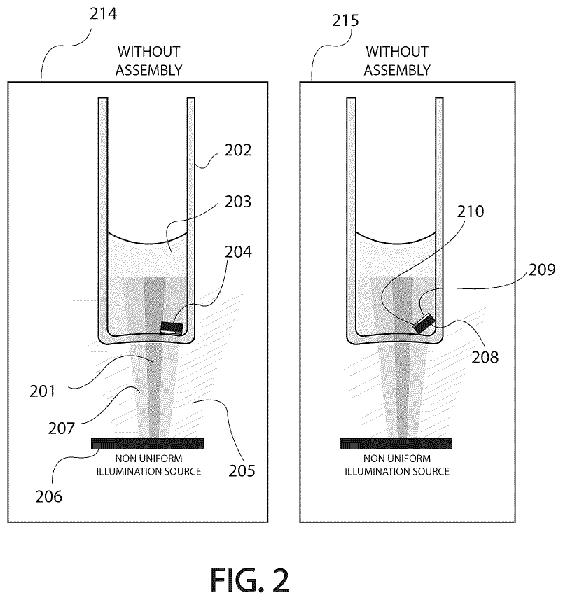

FIG. 2 illustrates configurations of bare optically powered semiconductor circuits in non-uniform light-illuminated fluid containers. The semiconductor circuits 204 and 208 and inside of fluid containing vials 202 and in fluid 203. In prior art, semiconductor circuits like those shown in FIG. 1 are manually inserted into such vials which are then filled with fluid and illuminated with light to run electrochemistry. For efficient and consistent operation, semiconductor circuits 204 are intended to have their photovoltaics 209 or light emitting elements 210 angled towards the illumination source 206. Many factors can move or change the configuration of the semiconductor circuits including the addition of fluid, vibrations or shocks during handling or transporting, and stirring or agitation methods. Two configurations are shown in 214 and 215. In 214 the semiconductor circuit has it's photovoltaics facing the illumination source 206 but is not aligned to the peak intensity 201 and is instead exposed to a weaker illumination level while in a fluid solution 203. The lower intensity light 207 and 205 is illuminated the regions further away from the center. In another configuration shown in 215, the semiconductor circuit's photovoltaics 209 towards the opening of the fluid container and are pointed away from the illumination source, only being indirectly exposed to light from the illumination source. The opaque substate of the semiconductor circuit prevents light from reaching the photovoltaics.

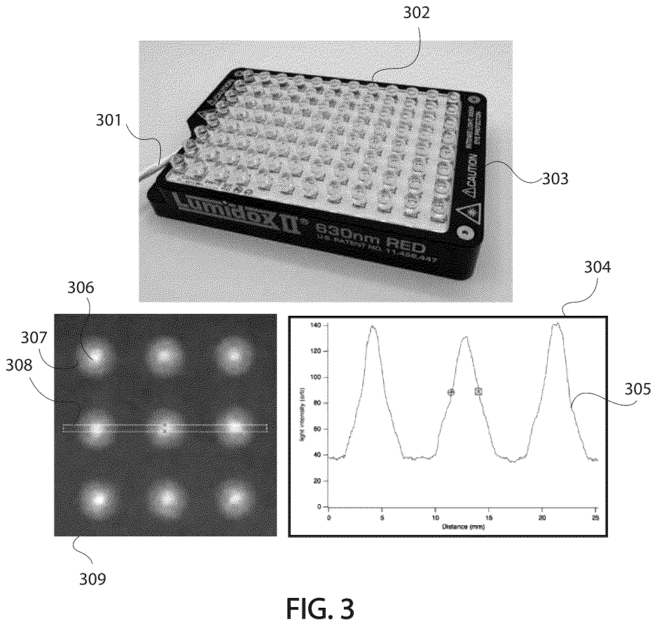

FIG. 3 shows an illumination source used in high-throughput biological and chemical experiments as well as data characterizing the spatial non-uniformity of the illuminator. The illumination source 303 is composed of 96 LEDs 302 that when powered provide high levels of light when connected through a wired power source 301. Such illumination sources are often used in photochemistry to excited molecules in solution with high levels of light. These sources are often very spatially non-uniform. Image 309 shows the optical output of a three-by-three array of the LEDs in the illumination source 303. The image shows a peak light intensity at the center 306 and a lower light intensity 307 further away from the center. Data from a cross section 308 of the image is shown in plot 304. The data 305 shows that there is a non-uniform light distribution with the peak intensity at the center of the LED. Even over the small scale of each LED illuminator, points even a few millimeters away from one another above the light source have dramatically different light levels. With this illumination source as the illumination source in FIG. 2, the semiconductor circuit inside of the fluid container would be exposed to vastly different amounts of light depending on where the semiconductor circuit was inside of the fluid container. A semiconductor circuit at the edge of a vial would be exposed to much less light than a semiconductor circuit at the center of a vial aligned to the LED from the illumination source.

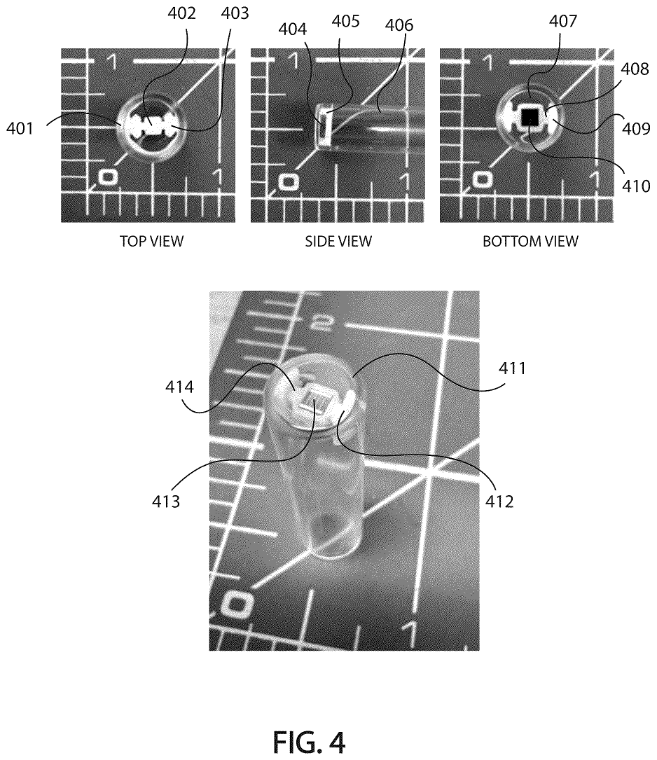

FIG. 4 shows one embodiment of the present disclosed optically powered semiconductor circuit assembly for light-illuminated fluid containers inside of an 8 mm diameter vial on a measurement reference surface. The optically powered semiconductor chip 413, also referred to as a semiconductor circuit, includes photovoltaic elements configured to generate power when illuminated by light and is mechanically coupled to a flexible component fixture 412 inside of a fluid container with the orientation of the photovoltaics fixed towards the sealed end of the fluid container, opposed to the opening of the fluid container. The top view shows the view of the assembly as seen from the opened end of the fluid container where the semiconductor circuit protected by a layer of the flexible component 402 and the flexible component's elements 203 have undergone sufficient mechanical deformation to secure the assembly in the fluid container due to forces exerted between the flexible component and the fluid containers inner walls 401. The optically powered semiconductor chip 413 is secured to the flexible component by mechanical deformation of the flexible component's edges 403, effectively press-fit into the flexible component. A side view shows that the assembly 405 is configured such that the semiconductor circuit is held above the bottom surface of the fluid container 406 with an open area 404 between the semiconductor circuit and the bottom of the fluid container. The bottom view shows the view of the assembly from the closed end of the fluid container where an optically transparent path to the semiconductor circuit 410 is exposed. The flexible component 412 has mechanical elements 414 and 408 configured to decouple the deformation used to secure the flexible component within the fluid container from the mechanical retention of the semiconductor circuit. The flexible component is configured to deform upon insertion into the fluid container, such that the deformation secures the assembly in a fixed position and orientation within the fluid container. The assembly is configured such that there is a pathway 407 that allows fluid to access the semiconductor circuit during use with fluid being able to go from above the semiconductor circuit to below the semiconductor circuit. In the illustrated embodiment, the flexible component 409 spans a plane transverse to the vertical axis of the fluid container, pressing laterally against the container walls to maintain position and orientation. This transverse orientation ensures that the photovoltaic elements remain consistently aligned with the external illumination source during use. In preferred embodiments, the photovoltaic elements of the semiconductor circuit are oriented toward the sealed end of the fluid container 411, facing away from the container opening, to ensure consistent alignment with a bottom-mounted light source. This geometry can be further scaled to small fluid container geometries such as 4 mm diameter vials, 384 well-plates, 1536 well-plates, and smaller volumes. Additionally this assembly can be scaled to larger dram vial fluid contains.

The flexible component illustrated in FIG. 4 is fabricated from 3D printed polypropylene, a chemically resistant thermoplastic polymer selected for its compatibility with a wide range of chemical environments. In certain embodiments, the disclosed assembly is intended for use in fluid containers that may contain aggressive solvents, acids, bases, or other chemically reactive species. For example, the embodiment of the assembly disclosed in FIG. 4 has demonstrated chemical stability when exposed to heated N-methyl-2-pyrrolidone (NMP) for many hours, a solvent commonly used in electrochemical applications and known to degrade many conventional materials. In such environments, adhesive bonding methods are generally unsuitable, as most glues and adhesives, such as UV cure glues or epoxies, fail to maintain adhesion or structural integrity when subjected to prolonged exposure to harsh chemicals or electrochemical conditions. Adhesives may also introduce contaminants through leaching or decomposition, which can interfere with sensitive reactions or measurements. Accordingly, in the embodiment shown in FIG. 4, the semiconductor circuit is secured to the flexible component solely through mechanical deformation of the flexible component, and the flexible component is retained within the fluid container by deformation-induced forces acting between the flexible component and the interior surface of the container. This adhesive-free configuration provides a chemically robust and mechanically stable solution for securely integrating optically powered semiconductor circuits into chemically diverse and operationally demanding fluidic environments.

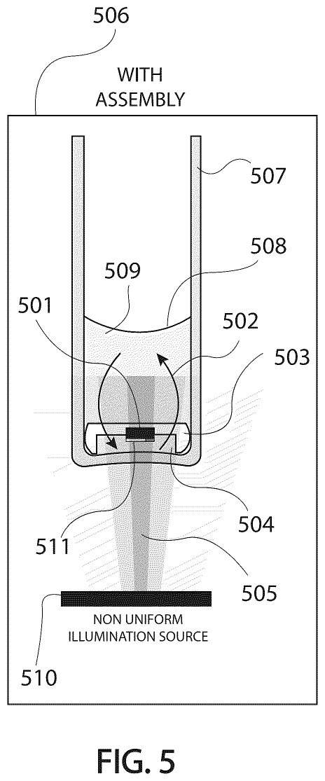

FIG. 5 illustrates a cross section 506 of one embodiment of the present disclosed optically powered semiconductor circuit assembly inside of a light-illuminated fluid container with fluid present. The assembly is composed of the semiconductor circuit 501 and the flexible component 503. The semiconductor circuit 501 is coupled to the flexible component 503 that has undergone deformation to fit inside of the fluid container 507. The orientation and position of the semiconductor circuit is fixed with the semiconductor circuit relatively centered in the fluid container with the photovoltaics of the semiconductor circuit 511 oriented towards the illumination source 510 and exposed to the peak intensity of light 505. The flexible component holds the position of the semiconductor circuit off of the bottom of the fluid container leaving space for fluid 504 and allowing for fluid flow from above the semiconductor circuit to below the semiconductor circuit so that the semiconductor circuit can be in contact with fluid that circulates inside of the fluid container through flows 502. In this embodiment the optically powered semiconductor circuit assembly is inside of fluid 509 with meniscus 508 while exposed to light.

In one embodiment, such a configuration as shown in FIG. 5 could be used to perform electrochemistry in a light-illuminated fluid container using an optically powered semiconductor circuit assembly. The assembly comprises a semiconductor circuit including one or more photovoltaic elements electrically connected to at least two exposed electrodes. When illuminated by light, the circuit applies a voltage between the exposed electrodes. In fluid environments, the exposed electrodes serve as a cathode and anode, driving current through the solution and performing electrochemical reactions. The semiconductor circuit is secured to a flexible component, where the flexible component is configured to deform upon insertion into the fluid container. As shown in FIG. 5, this deformation allows the flexible component to conform to the interior of the fluid container while simultaneously fixing the position and orientation of the semiconductor circuit within the container, ensuring that the photovoltaic elements are consistently oriented toward a light source external to the container.

In some embodiments, the semiconductor circuit includes onboard sensing elements, such as temperature, conductivity, or light sensors, that allow in situ monitoring of fluid conditions during experiments. These sensors may operate passively or be powered by the photovoltaic elements and can transmit data optically or electronically through the same interface used for circuit actuation. The optical communication system may include a photodiode or light-emitting element that transmits data in response to illumination events, environmental triggers, or programmed intervals, enabling the system to report real-time data wirelessly.

In this embodiment, reaction rate—effectively, how much desired product can be generated per time—is a key figure of merit. Because the reaction rate is limited by the maximum current that can be supplied by the circuit, and because maximum current is proportional to the amount of light incident of the photovoltaics, maximizing the light incident on the device improves performance. In practice, it is often easiest to deliver light to the photovoltaics by facing the photovoltaics toward the bottom of a transparent fluid container and shining light from beneath. This approach allows the light source to be placed a close and consistent distance from the photovoltaics without regard for the amount of fluid placed in the container or the presence or absence of a lid or seal. Moreover, if the photovoltaics can be consistently placed in a fixed location with respect to the light source, light can be focused onto the photovoltaics, permitting more efficient coupling and avoiding unnecessary heating of the solution from excess light.

However, in this embodiment, reaction rate can also be limited by mass transport—effectively, the amount of reactant that reaches the electrodes. If insufficient reactant reaches the electrodes, the amount of product that is generated decreases and, in some cases, the circuit can drive unintended reactions. While mass transport can occur passively via diffusion or convection, it is often significantly improved in electrochemical experiments by agitation or stirring.

To maximize reaction rates, therefore, the photovoltaics must be fixed in position and orientation to receive light efficiently in such a way that the fluid in the container can be mixed or stirred and that the fluid flow can reach the exposed electrodes on the device. Moreover, this must be done in a way that is robust to a wide range of chemistries, as electrochemical synthesis routinely uses aggressive solvents as well as strong acids and bases.

Once inserted, a solution is added to the fluid container such that the exposed electrodes are in contact with the fluid. The semiconductor circuit is held in a position elevated off the bottom of the container, allowing fluid to circulate around and beneath it. This positioning permits enhanced fluid dynamics and mass transport to the region near the electrodes, which is often critical for electrochemical reaction efficiency. Illumination is directed through a transparent portion of the fluid container, exposing the photovoltaic elements to peak intensity light and generating a voltage across the electrodes. This generated voltage is then used to drive an electrochemical reaction in the fluid.

By securing the semiconductor circuit in a stable, light-facing orientation and ensuring contact with the surrounding solution, this method enables precise, repeatable electrochemical operation without requiring external wiring, agitation-sensitive mounting, or custom reaction vessels. The combination of light-driven power generation, fixed spatial configuration, and fluid access allows for robust electrochemical reactions under a range of chemical conditions, including those involving mixing, stirring, or aggressive solvents.

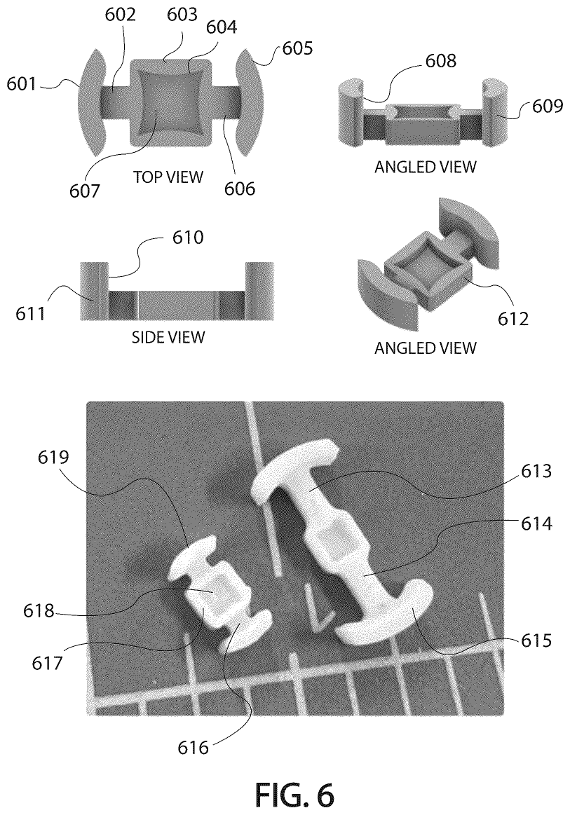

FIG. 6 shows 3D renderings of one embodiment of fixtures used for the present disclosed optically powered semiconductor circuit assembly for light-illuminated fluid containers, as well as manufactured embodiments of the fixtures. FIG. 6 includes top, side, and angled views of the flexible component, which is configured to secure an optically powered semiconductor circuit within a fluid container. The flexible component includes a recessed region 607 and 617 into which the semiconductor circuit is held. The dimensions of the recessed region are configured such that, in the absence of mechanical deformation, the semiconductor circuit cannot be inserted due to interference between the circuit and the inner edges 604 of the recess. When the flexible component is deformed during insertion of the circuit, the material flexes to temporarily accommodate the dimensions of the circuit, allowing it to be press-fit and mechanically secured within the fixture without the use of adhesives or fasteners. The angled view 612 provides another view of the flexible component. The side view 611 shows the height of the recessed region being different than the raised edges 610 that will deform to affix the assembly in the fluid container. The height of the elements 608 and 610 is chosen such that the semiconductor circuit is lifted off of the bottom sealed end of the fluid container. This configuration corresponds to the embodiments described in the claims, wherein the semiconductor circuit is secured to the flexible component through mechanical deformation.

Elements 606 and 602 are mechanical features that decouple the deformation of the outer edges of the flexible component 601 and 605, which engage with the interior wall of the fluid container, from the region 603 that retains the semiconductor circuit. This mechanical decoupling prevents stress from being transferred directly to the circuit during insertion or handling, thereby improving mechanical robustness and circuit retention. In addition, the flexible component 609 includes structural elements that elevate the semiconductor circuit off the bottom of the fluid container, allowing fluid to circulate beneath the circuit and enabling fluid flow paths consistent with those described in the claims. The figure also shows additional manufactured embodiments 615 and 617 of the flexible component, each designed for compatibility with fluid containers of different dimensions. In the embodiment 617 the recessed region 618 is shown along with edges 619 that are curved and will undergo deformation when inserted into the fluid container. These fixtures are fabricated using 3D printing with chemically resistant polypropylene, a material selected for its durability and inertness in the presence of harsh solvents and reagents. In particular, flexible component 615 includes elongated mechanical arms 613 and 614, which more visibly demonstrate the decoupling of container-facing deformation elements from the central region securing the semiconductor circuit. Smaller versions of these decoupling elements are included 616 in the smaller design. This design provides a stable, chemically compatible, and mechanically isolated method of securing and positioning an optically powered semiconductor circuit within a fluid container.

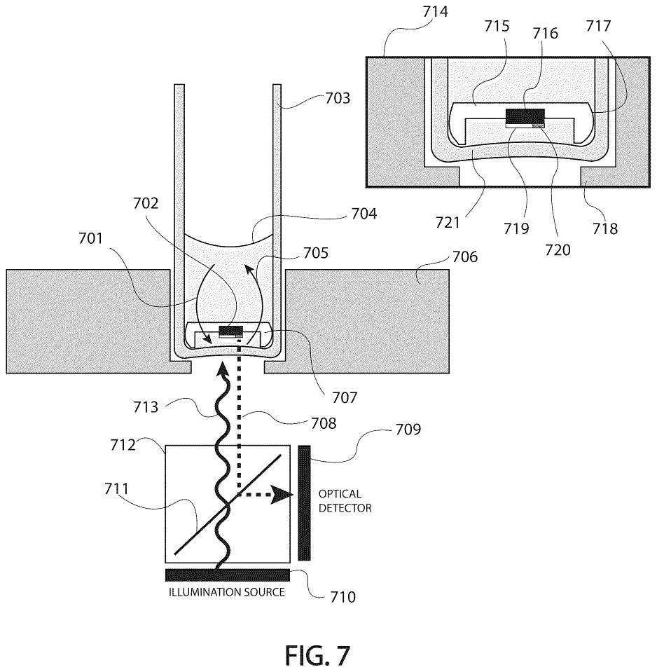

FIG. 7 illustrates cross-sectional views of one embodiment of the present disclosed optically powered semiconductor circuit assembly for light-illuminated fluid containers coupled to an optical illumination source and optical detector. A zoomed in cross section of the assembly in the fluid container is shown in 714. In this embodiment, the optically powered semiconductor circuit assembly 707 is held in a centered position and fixed orientation within a fluid container 703 containing fluid 704. The flexible component 715 secures the semiconductor circuit 702/716 by mechanical deformation, with structural elements 717 having undergone deformation to generate forces that retain the assembly in a stable configuration within the container. The photovoltaic elements of the semiconductor circuit 719 are oriented toward an external illumination source 710 positioned below the sealed bottom of the fluid container, such that light 713 is directed upward toward the circuit. The vials 703 and 720 is held in a reaction block 706 and 718, typically made of a polymer or metal. This configuration ensures efficient optical coupling between the light source and the photovoltaic elements 719 coupled through the transparent, sealed end of the vial 721, consistent with the embodiments described in the method and device claims relating to fixed orientation and illumination through a transparent portion of the container.

In this embodiment, the semiconductor circuit further includes a light-emitting element for optical communication. The light-emitting element, also indicated at 720, emits an optical signal 708, which is redirected through optical components 711, which includes a dichroic mirror supported in a housing 712 toward an optical detector 709. This configuration supports embodiments where the circuit communicates optically with an external system for purposes such as readout, feedback, or identification. The flexible component is configured to maintain the circuit's position without obstructing fluid dynamics, allowing fluid to flow 705/701 freely from above the semiconductor circuit to below it. This feature supports mass transport to the circuit's active surfaces and aligns with the claimed fluid access requirements. Together, these elements demonstrate a functional, optically and mechanically integrated system for powering and reading out a semiconductor circuit in a fluidic environment without the use of wires, adhesives, or custom containers.

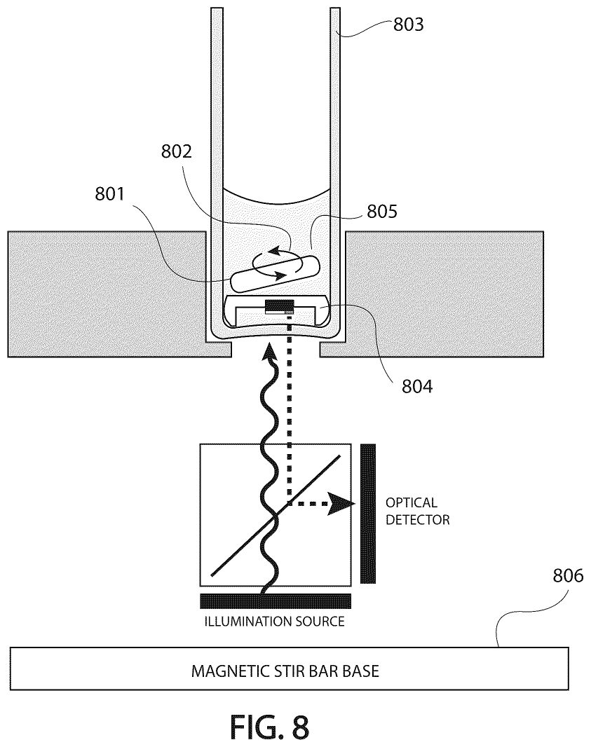

FIG. 8 illustrates a cross-sectional view of one embodiment of the present disclosed optically powered semiconductor circuit assembly for light-illuminated fluid containers, coupled to an optical illumination source and optical detector, with a magnetic stir bar system being simultaneously used. The flexible component 804 of the optically powered semiconductor circuit assembly is configured in a fluid container 803 such that a magnetic stir bar 801 is able to rotate 802 on top of the assembly while being actuated by a magnetic stir bar base 806 positioned beneath the fluid container. In this embodiment, the flexible component elevates the semiconductor circuit above the bottom of the fluid container and allows the stir bar to operate in close proximity to the circuit without making mechanical contact. This configuration protects the circuit from mechanical damage during mixing and ensures continued access to light and fluid 805.

The assembly remains fixed in position and orientation despite the forces introduced by stirring, with the photovoltaic elements of the semiconductor circuit maintained in alignment with an illumination source positioned below the container. Light from the illumination source passes through a transparent portion of the container and reaches the photovoltaic elements, enabling the circuit to generate power during operation. Simultaneously, the assembly allows fluid to circulate across and beneath the semiconductor circuit, promoting efficient mass transport in electrochemical or sensing applications. The compatibility of the assembly with standard magnetic stirring methods further demonstrates the robustness of the mechanically retained fixture and supports its applicability in high-throughput or chemically demanding environments.

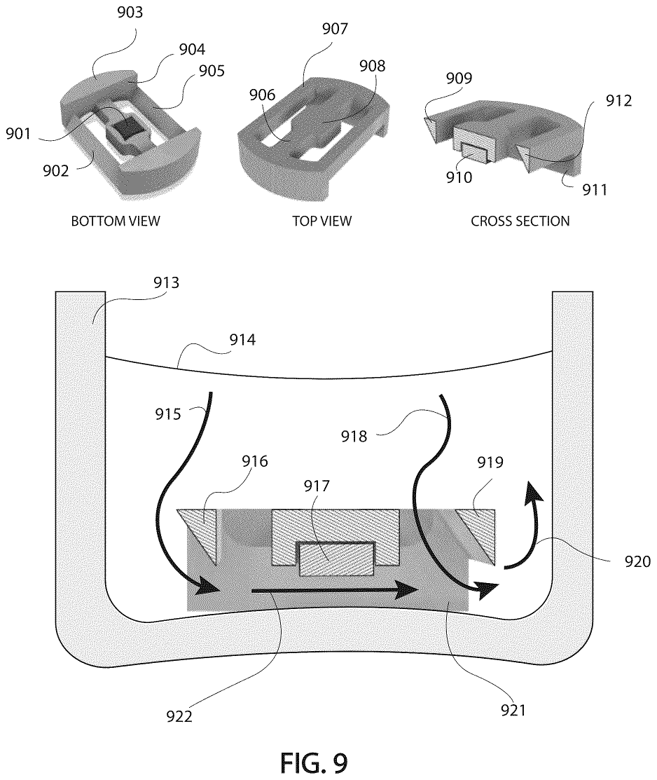

FIG. 9 illustrates one embodiment of the present disclosed optically powered semiconductor circuit assembly for light-illuminated fluid containers with angled elements that promote the flow of fluid to the optically powered semiconductor circuit. FIG. 9 includes 3D renderings of the assembly shown from a bottom view, top view, and a cross-sectional view, highlighting features of the flexible component that enhance fluid transport. The flexible component 903 includes angled elements 905 and 902 that are configured to promote directional fluid flow when a stirring element is present or when agitation induces bulk fluid motion within the container. This embodiment also has the raised elements 904, 911, and 921 to maintain the semiconductor circuit above the bottom sealed end of the fluid container. View 907 also shows the decoupling elements 906 for decoupling the deformation from the region 908 that holds the semiconductor circuit 901. The region 908 also protects the backside of the semiconductor circuit from agitation methods like stir bars. These angled surfaces 909, 912, 916, and 919 serve to redirect and guide fluid over and around the surface of the semiconductor circuit 901, 917, 910, increasing convective transport in regions that would otherwise rely solely on diffusion.

When submerged in fluid 914 inside a fluid container 913, the angled elements 916 and 919 create fluid flow patterns 915, 922, 918, and 920 that direct fluid from regions above the semiconductor circuit to regions below and across the active surface of the circuit. This geometry supports enhanced mass transport to the device and improves the efficiency of processes such as electrochemical reactions, sensing, or analyte collection. The angled elements act as passive flow guides that are fully integrated into the mechanically deformable flexible component and require no additional components or energy input. This configuration is consistent with embodiments described in the claims that include structural features for promoting fluid flow and circulation while maintaining a fixed circuit orientation and preserving compatibility with stirring and chemically aggressive environments.

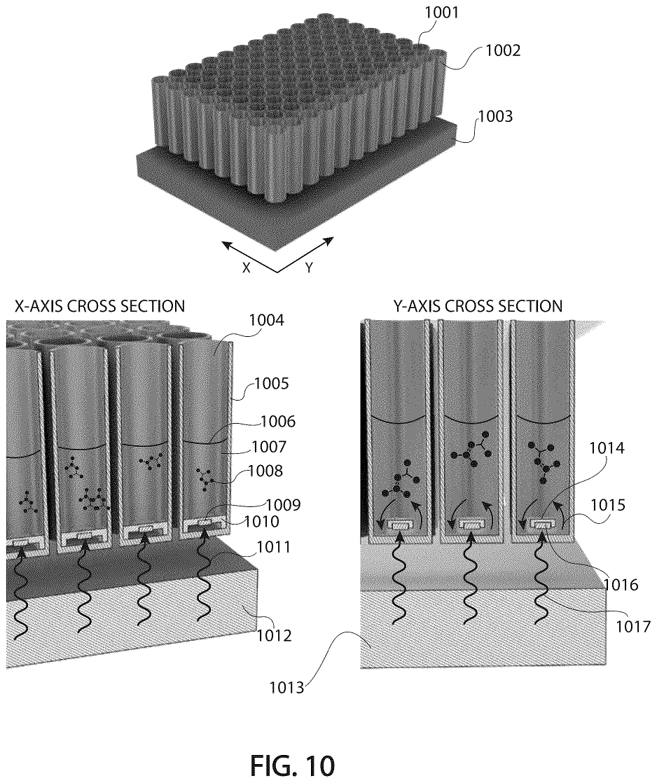

FIG. 10 illustrates cross-sectional views of a 96 well plate of vials under illumination with some embodiments of present disclosed optically powered semiconductor circuit assemblies for light-illuminated fluid containers. FIG. 10 includes 3D renderings of an 8 mm, 96-well plate vial array 1002 with the openings of the individual vials 1001 positioned opposed to the illumination block 1003 containing embedded light-emitting elements, along with zoomed-in cross-sectional views along both the x-axis and y-axis. These views schematically highlight key features of the assembly in an embodiment configured for high-throughput chemical experimentation. In each vial 1004, a semiconductor circuit 1009 or 1016 is secured to a flexible component 1010 or 1014, which holds the circuit above the sealed bottom surface of the vial. The assembly is press-fit into position such that the flexible component engages with the inner sidewall 1005 of the vial, maintaining the semiconductor circuit in a fixed orientation with the photovoltaic elements directed toward the illumination source.

Each vial is filled with liquid 1007 containing reactants 1008, and the liquid's meniscus 1006 rises above the level of the assembly, fully submerging the semiconductor circuit. Illumination is provided by a block-integrated light source 1012, 1013, which emits light 1011 and 1017 upward through the transparent bottom of the vial and onto the photovoltaic surface of the semiconductor circuit. Along the x-axis, the assembly spans the internal width of the vial and contacts the vial walls to maintain a stable lateral position. Along the y-axis, however, intentional gaps between the flexible component and the vial walls are present. These gaps permit fluid to circulate beneath the semiconductor circuit 1015, enabling diffusion and convective mixing of reactants and allowing electrochemical or sensing elements onboard the semiconductor circuit to interact directly with the surrounding solution.

This embodiment of the present disclosed optically powered semiconductor circuit assembly enables up to 96 discrete chemical or biological experiments to be conducted in parallel using small fluid volumes and standard labware formats. The configuration is fully compatible with automated liquid handling systems commonly used in high-throughput experimentation workflows and supports scalable, wire-free, optically powered operation of integrated microscale devices within each well.

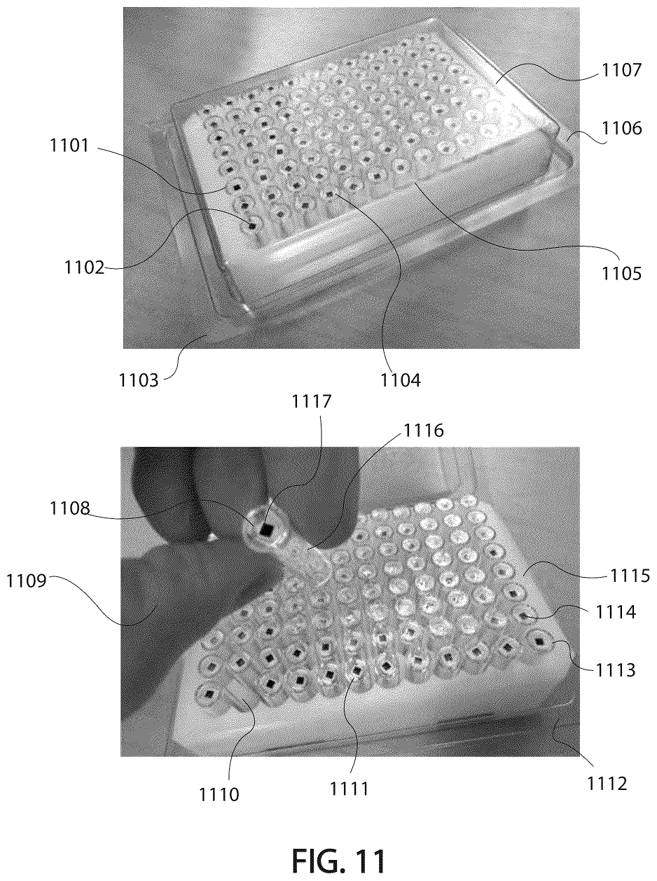

FIG. 11 shows a pre-populated 96-well plate of vials with one embodiment of the present disclosed optically powered semiconductor circuit assembly for light-illuminated fluid containers in a container suitable for shipment. The assembly 1102, 1104, and 1111, including a semiconductor circuit 1117 mechanically secured to a flexible component 1108, is placed into standard 8 mm vials 1101 and 1116. In this embodiment the photovoltaics of the semiconductor assembly 1114 is oriented towards the bottom sealed end of the vial 1113. A total of ninety-six vials, each containing one such assembly, are arranged in a repeating array and placed into trays 1105 and 1115, which include openings 1110 sized to match the outer diameter of the vials, maintaining consistent spacing and orientation throughout the tray.

For shipping and storage, the tray is enclosed within a shipping container or box 1103 and 1112, which includes a lid 1107 and a retaining clip 1106 to prevent displacement of the vials during handling, storage, or inversion. In testing, the boxed assembly has been subjected to accelerations of 1 g, 5 g, 10 g, and up to 50 g, and all 96 assemblies remained securely fixed in their respective positions and orientations. In various shipping and handling tests, assemblies retained their position and orientation under acceleration forces of at least 5 g, and in some cases up to 50 g. This demonstrates the suitability of the design for transport in standard laboratory and industrial logistics environments without requiring reassembly or adjustments. The mechanical retention of the assemblies within the vials is achieved solely through deformation of the flexible components against the inner vial walls, without the use of adhesives, fasteners, or secondary restraints. A user can open the box and manually remove individual vials by hand 1109 for experimental use. This packaging configuration enables robust, high-density distribution of pre-populated, optically powered semiconductor circuit assemblies, supporting deployment in high-throughput experimentation environments with minimal risk of disruption during transport.

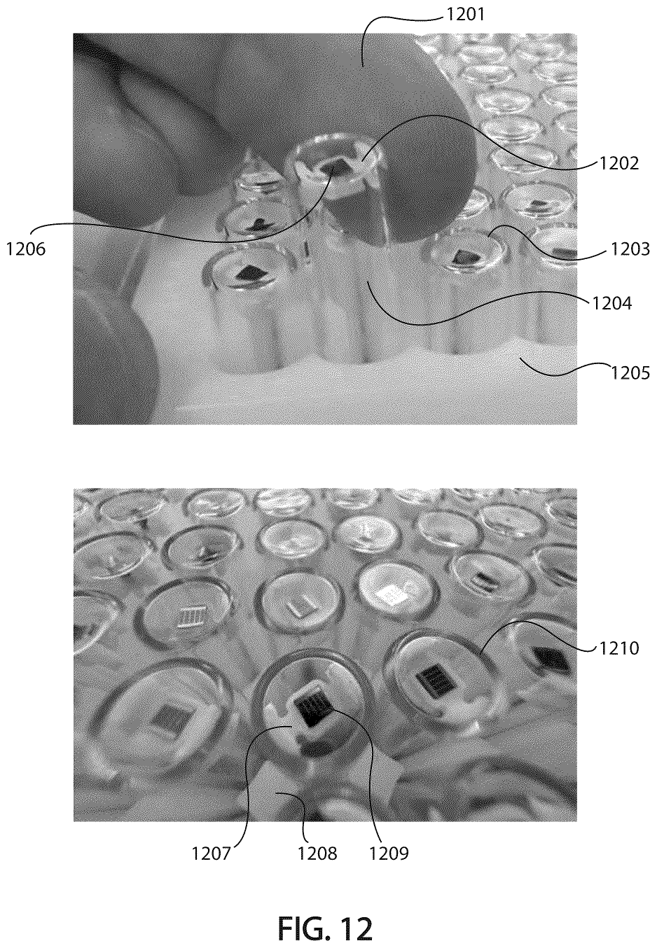

FIG. 12 shows a zoomed-in image of a prepopulated 96-well plate of vials with one embodiment of the present disclosed optically powered semiconductor circuit assembly for light-illuminated fluid containers. In this embodiment, a plurality of semiconductor circuit assemblies—each comprising a semiconductor circuit 1209 and a flexible component 1207—are inserted into individual vials 1210, 1203. The vials are arranged in a repeating array within a 96-position vial holder plate 1208, which maintains the vials at fixed spacing and orientation. Each vial contains a semiconductor circuit assembly held securely in place by mechanical deformation of the flexible component 1202, which conforms to the inner walls of the vial and retains the assembly in a fixed position and orientation without adhesives.

As shown in the figure, the vials 1204 can be removed either individually or in parallel for transfer into an assay block or reactor system. In this particular embodiment, a hand 1201 is manually removing one of the vials 1204 from the holder block 1205, with the vial oriented opening-down and sealed end up. Despite inversion, the semiconductor circuit assembly remains fixed in position with the photovoltaic elements 1206 oriented toward the sealed bottom of the fluid container, enabling bottom illumination. The assemblies are retained entirely by the deformation-induced forces of the flexible components. In this embodiment, each semiconductor circuit includes both photovoltaic elements and exposed electrodes configured for electrochemical applications. When the fluid container is filled with solution and illuminated from below through a transparent portion of the container, the photovoltaic elements generate a voltage across the electrodes, enabling electrochemical reactions within the fluid. This configuration is suitable for drug discovery and high-throughput experimentation, providing a scalable, wire-free, and chemically robust platform for parallelized electrosynthesis and analysis.

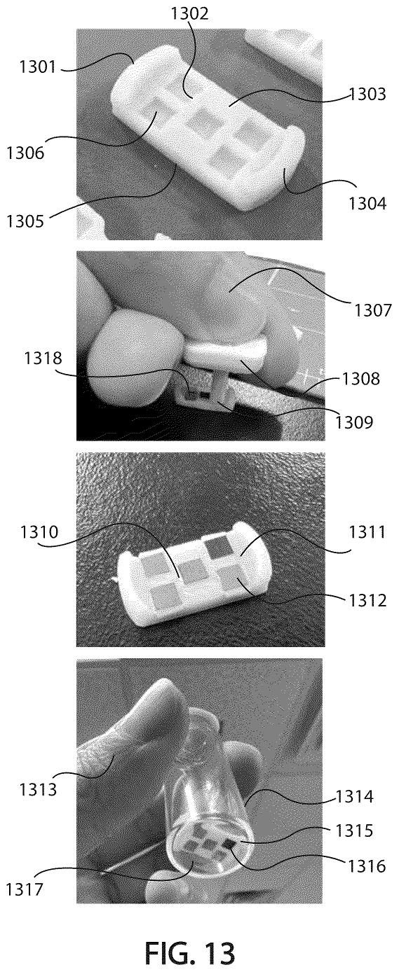

FIG. 13 shows the process of insertion of optically powered semiconductor circuits through mechanical deformation into the flexible fixtures for an optically powered semiconductor circuit assembly for drams. This figure includes four images illustrating progressive steps in the assembly and integration process. In the first image, a flexible component 1303 is shown with dimensions appropriate for a dram vial with a screw-top opening. The flexible component includes five recessed regions 1306, each configured to receive a semiconductor circuit. The inner edges of the recessions 1302 are dimensioned such that, in the absence of mechanical deformation, the semiconductor circuits cannot be inserted into the recessions. The flexible component also includes outer edges 1301 and 1304 along the long axis 1305 that exceed the inner diameter of the dram vial's opening, such that the component cannot be inserted into the vial in a planar orientation relative to the vial bottom without deformation. The recessed regions 1306 further include a protective layer configured to shield the inserted semiconductor circuits from mechanical agitation elements such as magnetic stir bars, magnetic tumblers, or mixing beads during operation.

The second image shows a user 1307 manually press-fitting a semiconductor circuit into the flexible component 1309 using a soft instrument 1308 for insertion. A semiconductor circuit 1318 is shown positioned above the recess prior to insertion, demonstrating that mechanical deformation is required for the circuit to be secured within the flexible component. In the third image, the flexible component 1311 is shown after successful insertion of five semiconductor circuits 1312, each held in place through deformation of the surrounding material. The outer edges 1310 of the flexible component have also undergone deformation, preparing the assembly for insertion into a dram vial. The final image shows the completed assembly inserted into a fluid container 1314 in the form of a dram vial being held by a user 1313. The assembly is retained in a fixed position and orientation by deformation of the outer edges 1315, which generate holding forces against the interior wall of the container. The semiconductor circuits 1316 are elevated above the sealed bottom of the vial and are not in contact with the container's base. In addition, openings 1317 are present in the flexible component to allow fluid to flow from above to below the circuits, enabling submersion and continuous fluid contact during use. This embodiment supports scalable assembly, secure fixation, fluid accessibility, and mechanical protection, and is consistent with the design principles and requirements addressed in the present disclosure.

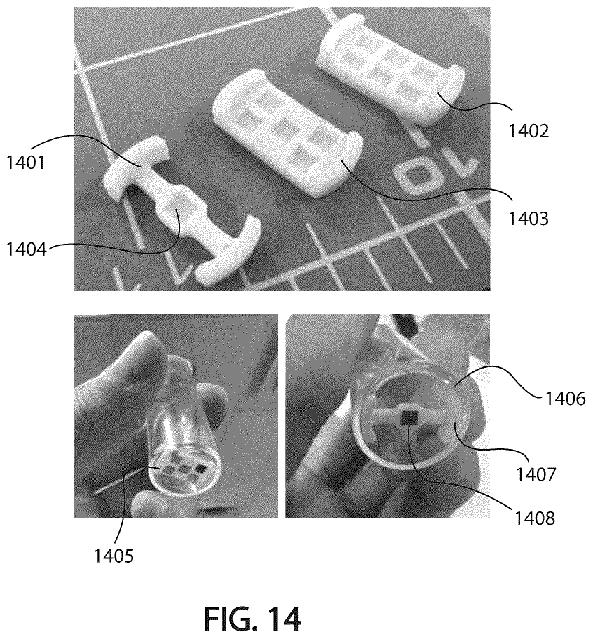

FIG. 14 shows various embodiments of the present disclosed optically powered semiconductor circuit assembly for light-illuminated dram vials. The figure illustrates multiple design variations of flexible components fabricated from chemically resistant polypropylene. Embodiments 1404, 1403, and 1402 each represent fixtures configured to receive and retain one or more optically powered semiconductor circuits. Flexible component 1404 is designed for the integration of a single semiconductor circuit 1408 and is configured such that, when the assembly is completed and inserted into a dram vial 1406, the circuit is centered within the vial. In this embodiment, the edges 1407 of the flexible component have undergone mechanical deformation, securing the assembly in a fixed position and orientation within the container. The design minimizes the amount of material obstructing fluid flow, thereby maximizing the volume of fluid that can circulate and make contact with the surface of the semiconductor circuit 1408.

The flexible component 1404 further includes structural elements 1401—long, thin mechanical arms extending from the recessed region—that are configured to decouple the deformation of the outer edges (used to secure the assembly within the container) from the recession that retains the semiconductor circuit. This mechanical decoupling prevents stress from being transferred directly to the circuit during insertion or handling. Additional embodiments are shown in fixtures 1403 and 1402, which are designed to accommodate five and six semiconductor circuits, respectively. A fully assembled example of the embodiment accommodating five circuits is shown inserted into a dram vial, where five semiconductor circuits 1405 are retained entirely through mechanical deformation of the flexible component. No adhesives, glues, or epoxies are used in this configuration. These embodiments demonstrate the adaptability of the disclosed assembly design to support different circuit counts and fluid container geometries while preserving chemical compatibility, structural stability, and functional alignment with optical and fluidic requirements.

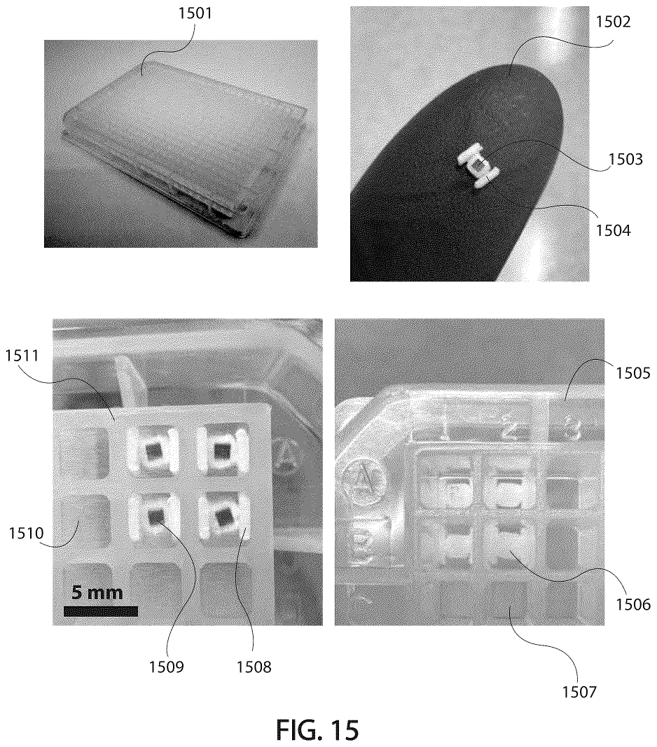

FIG. 15 shows an embodiment of the present disclosed optically powered semiconductor circuit assembly for light-illuminated 384-well plates, another common platform for high-throughput experiments in chemistry and biology. FIG. 15 includes images of a 384-well plate 1501 and an embodiment of the assembly 1504 designed to fit within individual wells of such a plate. The images show the assembly both outside of and inserted into the well plate, viewed from above and below. One image depicts the assembly resting on a gloved finger 1502 for scale, demonstrating the compactness of the configuration. This embodiment includes of a 1-mm square semiconductor circuit 1503 and 1509 mechanically coupled to a flexible component 1504, 1506, and 1508 through deformation. The flexible component is configured to deform upon insertion into an individual well 1507 and 1510, generating sufficient force against the walls of the fluid container 1511 to retain the assembly in a fixed position and orientation within the fluid container. The labeled edge 1505 of the well plate is show in FIG. 15.

The semiconductor circuit is elevated above the bottom surface of the well by the geometry of the flexible component, promoting fluid access and enhanced mass transport across the surface of the circuit. The assembly shown in this embodiment retains the core features described in earlier figures: mechanical retention of the circuit within the flexible component and deformation-based fixation of the entire assembly within the container, all without the use of adhesives or fasteners. This embodiment demonstrates the scalability of the disclosed design to accommodate various standard container geometries and sizes. Populating an entire 384-well plate with such assemblies enables 384 optically powered semiconductor circuits to operate in parallel, facilitating high-throughput electrochemical reactions, sensing, or measurements across a broad array of chemical or biological samples.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described. Various embodiments are described by the following set of clauses or claims.

What is claimed is:

1. An assembly comprising:
a semiconductor circuit comprising one or more photovoltaic elements configured to generate power when illuminated by light; and
a flexible component mechanically coupled to the semiconductor circuit, wherein:
the flexible component is configured to deform upon insertion into a fluid container, such that the deformation secures the assembly in a fixed position and orientation within the fluid container;
the flexible component is configured to hold the semiconductor circuit with the photovoltaic elements in the fixed position and orientation; and
wherein the assembly allows fluid to access the semiconductor circuit during use.

2. The assembly of claim 1, wherein the flexible component comprises structural elements that raise the semiconductor circuit above a bottom surface of the fluid container, such that the semiconductor circuit is fully immersed in fluid during use.

3. The assembly of claim 1, wherein the flexible component does not occlude fluid flow from above the assembly to below the assembly.

4. The assembly of claim 1, wherein the flexible component positions the semiconductor circuit such that the one or more photovoltaic elements face away from an opening of the fluid container.

5. The assembly of claim 1, wherein the semiconductor circuit is secured to the flexible component by mechanical deformation of the flexible component.

6. The assembly of claim 1, wherein the flexible component includes one or more mechanical elements configured to decouple the deformation used to secure the flexible component within the fluid container from mechanical retention of the semiconductor circuit.

7. The assembly of claim 1, wherein the flexible component is configured to maintain the fixed position and orientation of the semiconductor circuit during fluid mixing without dislodging or damaging the semiconductor circuit.

8. The assembly of claim 1, further comprising a magnetic stir bar resting on or above the assembly.

9. The assembly of claim 8 further comprising a layer disposed between the magnetic stir bar and the semiconductor circuit.

10. The assembly of claim 1, wherein the semiconductor circuit further comprises a sensor configured to detect an environmental or chemical property of the fluid.

11. The assembly of claim 1, wherein the fluid container is transparent.

12. The assembly of claim 1, wherein the photovoltaic elements are configured to receive light from an illumination source positioned below the container.

13. The assembly of claim 1, wherein the semiconductor circuit comprises electrodes in contact with the fluid and is configured to drive electrochemical reactions between the electrodes when powered by light.

14. The assembly of claim 1, wherein the semiconductor circuit comprises an array of photovoltaics to perform electrochemistry.

15. The assembly of claim 1, wherein the assembly includes no adhesive with the semiconductor circuit retained within the flexible component solely through mechanical deformation.

16. The assembly of claim 1, wherein the assembly is configured for use with an optical communication system to receive data from the semiconductor circuit.

17. The assembly of claim 1, wherein the assembly is configured for use with an optical communication system to transmit data to the semiconductor circuit.

18. The assembly of claim 1, wherein the flexible component includes one or more angled surfaces configured to drive fluid flow toward the semiconductor circuit in the presence of stirring or agitation.

19. The assembly of claim 1, wherein the flexible component is formed from a chemically resistant material produced using a 3D printing process.

20. The assembly of claim 1, wherein the flexible component comprises polypropylene.
